(19) United States
(12) Patent Application Publication
(10) Pub. No.: US 2025/0183158 A1
(43) Pub. Date: Jun. 5, 2025

(54) SEMICONDUCTOR DEVICE INCLUDING VIA STRUCTURE CONNECTED TO BACKSIDE POWER DELIVERY NETWORK

(71) Applicant: SAMSUNG ELECTRONICS CO., LTD., Suwon-si (KR)

(72) Inventors: Sangeun YUN, Suwon-si (KR); Boram LEE, Suwon-si (KR)

(73) Assignee: SAMSUNG ELECTRONICS CO., LTD., Suwon-si (KR)

(21) Appl. No.: 18/940,301

(22) Filed: Nov. 7, 2024

(30) Foreign Application Priority Data
Dec. 5, 2023 (KR) 10-2023-0174762

(51) Int. Cl. H01L 23/522; H01L 21/762; H01L 23/528; H01L 27/092; H01L 29/06; H01L 29/66; H01L 29/775; H01L 29/786

(52) U.S. Cl. CPC H01L 23/5226; H01L 23/5286; H10D 62/115; H10D 62/127; H10D 84/856; H01L 21/76229; H10D 30/014; H10D 30/43; H10D 30/6757; H10D 62/121; H10D 84/853

(57) ABSTRACT

A semiconductor device may include: an active pattern on a substrate; a substrate recess formed in an upper portion of the substrate in a third direction intersecting a bottom surface of the substrate; a first interconnection layer above the active pattern in the third direction; a power delivery network layer below the bottom surface of the substrate in the third direction; and a penetration via pattern electrically connecting the first interconnection layer to the power delivery network layer, wherein the penetration via structure is provided in the substrate recess, and a side surface of the penetration via structure is spaced apart from an inner side surface of the substrate recess.

### CROSS-REFERENCE TO RELATED APPLICATIONS

This application claims priority to Korean Patent Application No. 10-2023-0174762, filed on Dec. 5, 2023, in the Korean Intellectual Property Office, the disclosure of which is incorporated herein by reference.

### BACKGROUND

Methods and apparatuses consistent with the embodiments of the disclosure relate to a semiconductor device including a field-effect transistor and a method of fabricating the same.

A semiconductor device includes an integrated circuit in which a plurality of metal-oxide-semiconductor field-effect transistors (MOSFETs) are formed. To meet an increasing demand for a semiconductor device with a small pattern size and a reduced design rule, the MOSFETs are being aggressively scaled down. The scale-down of the MOSFETs may lead to deterioration in operational properties of the semiconductor device. A variety of studies are being conducted to overcome technical limitations associated with the scale-down of the semiconductor device and to realize high-performance semiconductor devices.

### SUMMARY

One or more embodiments of the disclosure provide a semiconductor device with improved productivity and a method of fabricating the same.

According to one or more embodiments, there is provided a semiconductor device which may include: an active pattern on a substrate; a substrate recess formed in an upper portion of the substrate in a third direction intersecting a bottom surface of the substrate; a first interconnection layer above the active pattern in the third direction; a power delivery network layer below the bottom surface of the substrate in the third direction; and a penetration via pattern electrically connecting the first interconnection layer to the power delivery network layer, wherein the penetration via structure is provided in the substrate recess, and a side surface of the penetration via structure is spaced apart from an inner side surface of the substrate recess.

According to one or more embodiments, there is provided a semiconductor device which may include: an active pattern on a substrate; a device isolation pattern comprising a first region enclosing the active pattern and a second region filling a recess formed in an upper portion of the substrate; a first interconnection layer above the active pattern in a third direction intersecting a bottom surface of the substrate; a power delivery network layer below a bottom surface of the substrate in the third direction; and a penetration via pattern electrically connecting the first interconnection layer to the power delivery network layer, wherein the penetration via pattern penetrates the first and second regions of the device isolation pattern.

According to one or more embodiments, there is provided a semiconductor device which may include: an active pattern on a substrate; a device isolation pattern comprising a first region enclosing the active pattern and a second region filling a recess formed in an upper portion of the substrate; a channel structure on the active pattern; a source/drain pattern connected to the channel structure; a gate electrode on the channel structure; an active contact connected to the source/drain pattern; a first interconnection layer above the active contact in a third direction intersecting a bottom surface of the substrate; a power delivery network layer below a bottom surface of the substrate; and a penetration via pattern electrically connecting the first interconnection layer to the power delivery network layer, wherein the penetration via pattern penetrates the first and second regions of the device isolation pattern.

### BRIEF DESCRIPTION OF DRAWINGS

FIGS. 1 to 3 are conceptual diagrams illustrating logic cells of a semiconductor device, according to one or more embodiments.

FIG. 4 is a plan view illustrating a semiconductor device, according to one or more embodiments.

FIGS. 5A-5D are cross-sectional views of the semiconductor device of FIG. 4 taken along lines A-A′, B-B′, C-C′, and D-D′, respectively, shown in FIG. 4, according to one or more embodiments.

FIGS. 6A to 12 are diagrams illustrating a method of fabricating a semiconductor device, according to one or more embodiments.

### DETAILED DESCRIPTION

Example embodiments will now be described more fully with reference to the accompanying drawings, in which example embodiments are shown.

It is to be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. It is also to be understood that the terms “first,” “second,” “third,” “fourth,” etc. used herein to describe various elements, components, regions, layers and/or directions (collectively “elements”) are consistently used both in the description section and the claims of the present application to assist better understanding of the disclosure. For example, a “third direction” mentioned in a claim may indicate or represent a “third direction” described in the description section.

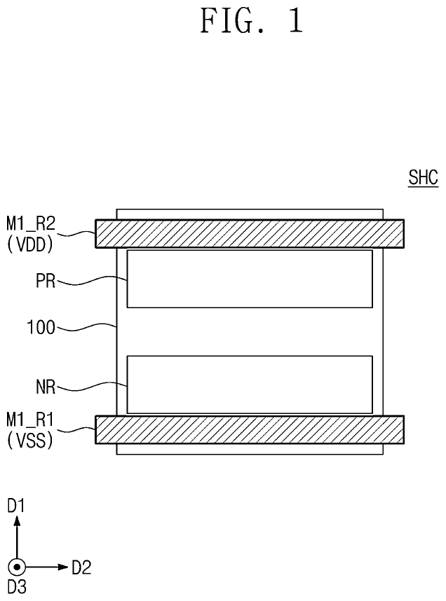

FIGS. 1 to 3 are conceptual diagrams illustrating logic cells of a semiconductor device according to one or more embodiments.

Referring to FIG. 1, a single height cell SHC may be provided, in which a first power line M1_R1 and a second power line M1_R2 may be provided on a substrate 100. The first power line M1_R1 may be a conduction path through which a first voltage VSS (e.g., a ground voltage) is provided. The second power line M1_R2 may be a conduction path through which a second voltage VDD (e.g., a power voltage) is provided.

The single height cell SHC may be defined between the first power line M1_R1 and the second power line M1_R2. The single height cell SHC may include one p-type metal-oxide-semiconductor field-effect transistor (PMOSFET) region PR and one n-type metal-oxide-semiconductor field-effect transistor (NMOSFET) region NR. The PMOSFET region PR and the NMOSFET region NR may be arranged and spaced apart from each other in a first direction D1 (cell height direction) and may be extended in a second direction D2. The first and second directions D1 and D2 may be parallel to a top or bottom surface of the substrate 100, and may not be parallel to each other.

The single height cell SHC may constitute a single logic cell. In the present specification, the logic cell may implement a logic device (e.g., AND, OR, XOR, XNOR, inverter, and so forth), which is configured to execute a specific function. The logic cell may include transistors constituting the logic device and interconnection lines connecting the transistors to each other or other circuit elements in the logic cell or another cell of the semiconductor device.

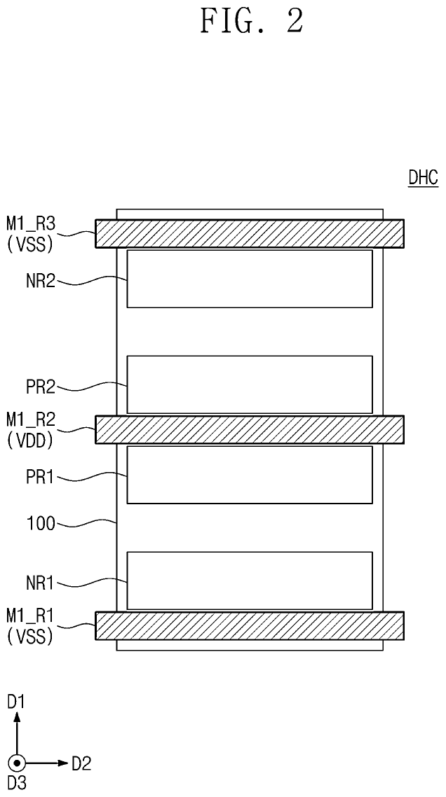

Referring to FIG. 2, a double height cell DHC may be provided, in which a first power line M1_R1, a second power line M1_R2, and a third power line M1_R3 may be provided on the substrate 100. The second power line M1_R2 may be disposed between the first power line M1_R1 and the third power line M1_R3. The first power line M1_R1 and the third power line M1_R3 may each be a conduction path through which a first voltage VSS is provided, and the second power line M1_R2 may be a conduction path through which a second voltage VDD is provide.

The double height cell DHC may be defined between the first power line M1_R1 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the first power line M1_R1. The second NMOSFET region NR2 may be adjacent to the third power line M1_R3. The first and second PMOSFET regions PR1 and PR2 may be adjacent to the second power line M1_R2. The first and second PMOSFET regions PR1 and PR2 may be disposed to be opposite to each other with respect to the second power line M1_R2 in the first direction D1. The first and second PMOSFET regions PR1 and PR2 of the double height cell DHC may serve as a single PMOSFET region.

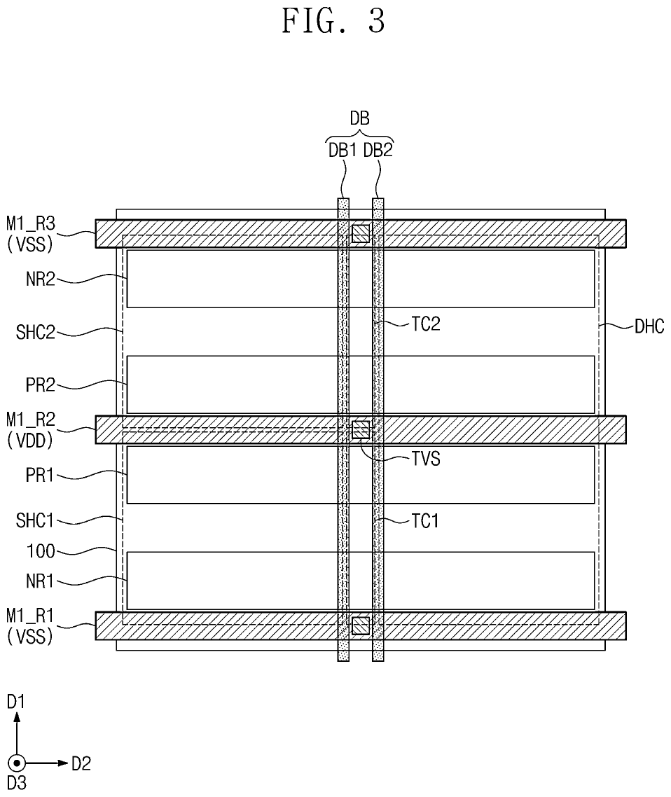

Referring to FIG. 3, a first single height cell SHC1, a second single height cell SHC2, and a double height cell DHC may be two-dimensionally disposed on the substrate 100. The second single height cell SHC2 may be adjacent to the first single height cell SHC1 in the first direction D1. The double height cell DHC may be adjacent to the first and second single height cells SHC1 and SHC2 in the second direction D2.

A first tap cell TC1 may be provided between the first single height cell SHC1 and the double height cell DHC. A second tap cell TC2 may be provided between the second single height cell SHC2 and the double height cell DHC. Each of the first and second tap cells TC1 and TC2 may be a cell, which is used to apply a voltage from a power delivery network layer, which will be described below, to at least one of the power line M1_R1, M1_R2, and M1_R3. Each of the first and second tap cells TC1 and TC2 may include a penetration via structure TVS, which is used to electrically connect a corresponding one of the power lines M1_R1, M1_R2, and M1_R3 to the power delivery network layer.

A first division structure DB1 may be provided between the first tap cell TC1 and the first single height cell SHC1 and between the second tap cell TC2 and the second single height cell SHC2. A second division structure DB2 may be provided between the first tap cell TC1 and the double height cell DHC and between the second tap cell TC2 and the double height cell DHC. The first and second division structures DB1 and DB2 may be extended across the first to third power lines M1_R1, M1_R2 and M1_R3 in the first direction D1. An active region of the logic cell SHC1, SHC2, or DHC may be electrically disconnected from an active region of the tap cell TC1 or TC2 by a division structure DB, which collectively represent the first and second division structures DB1 and DB2.

FIG. 3 illustrates an example arrangement of the first and second tap cells TC1 and TC2 and the logic cells SHC1, SHC2, and DHC, but the arrangement of the logic and tap cells may be variously changed.

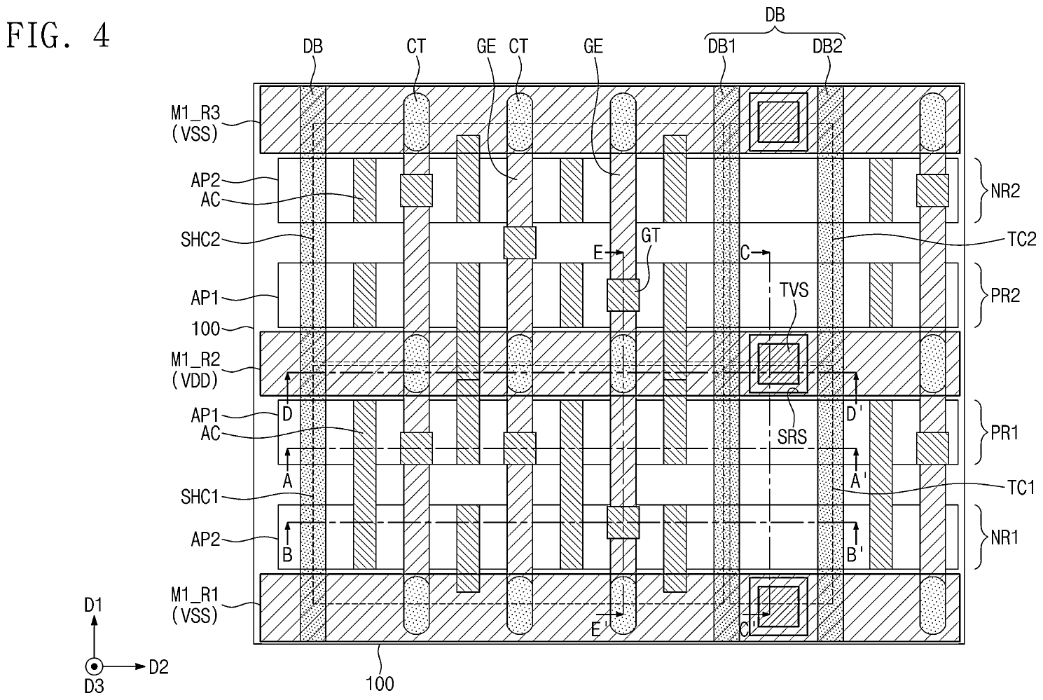

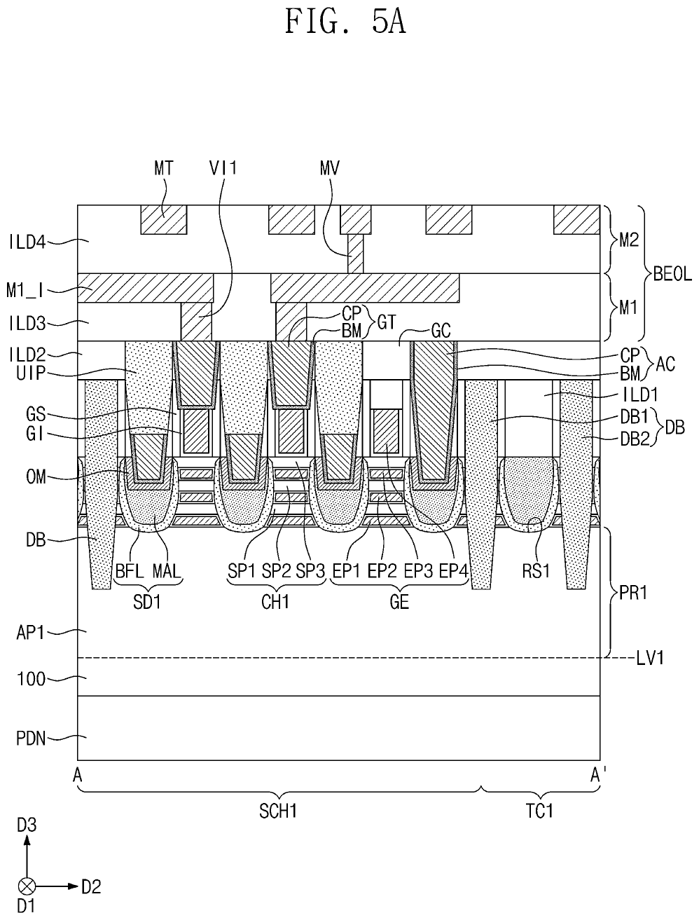

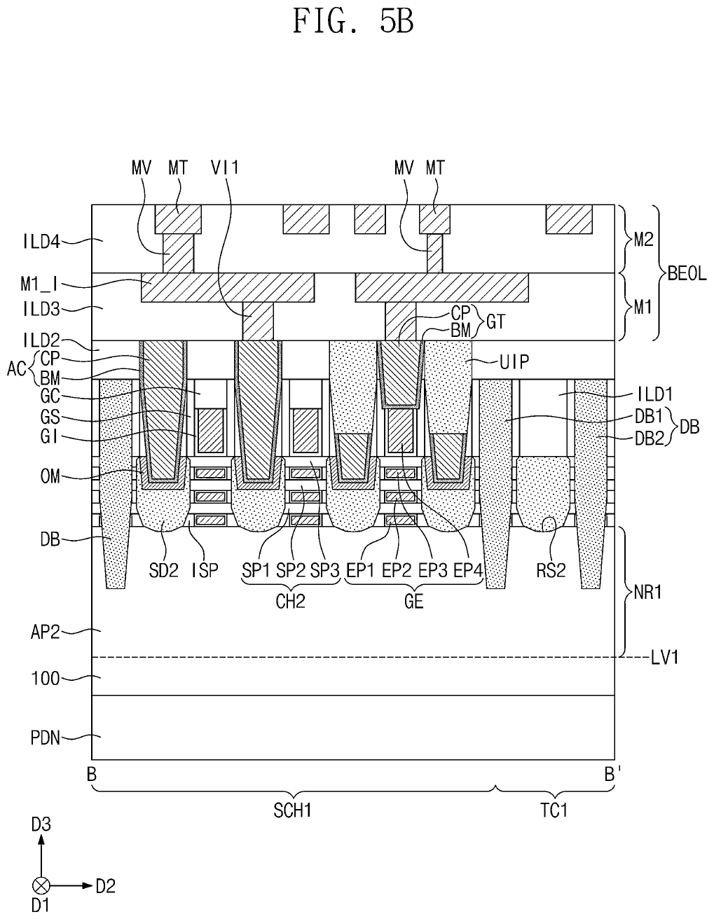

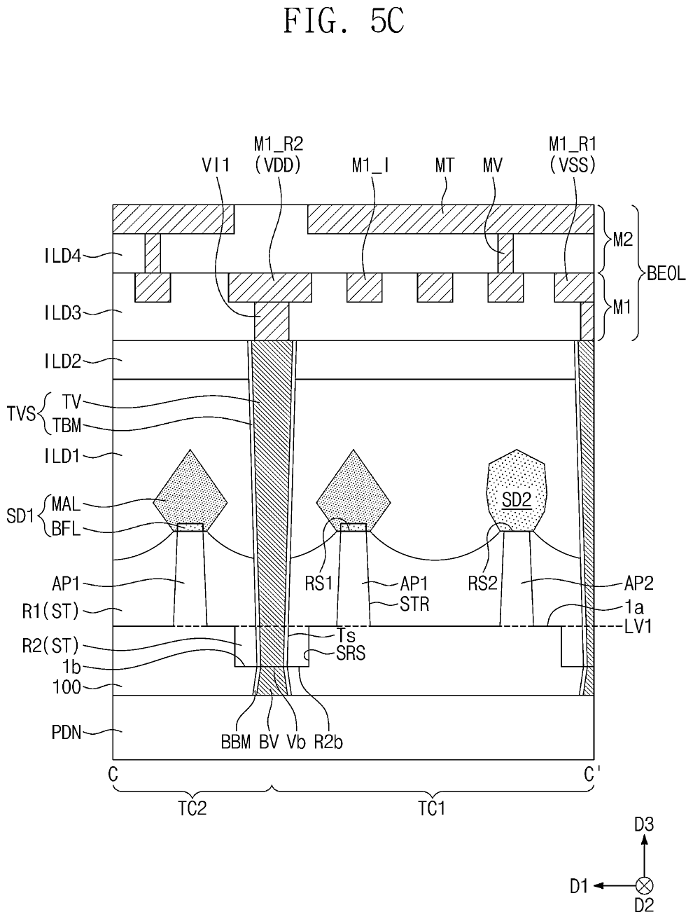

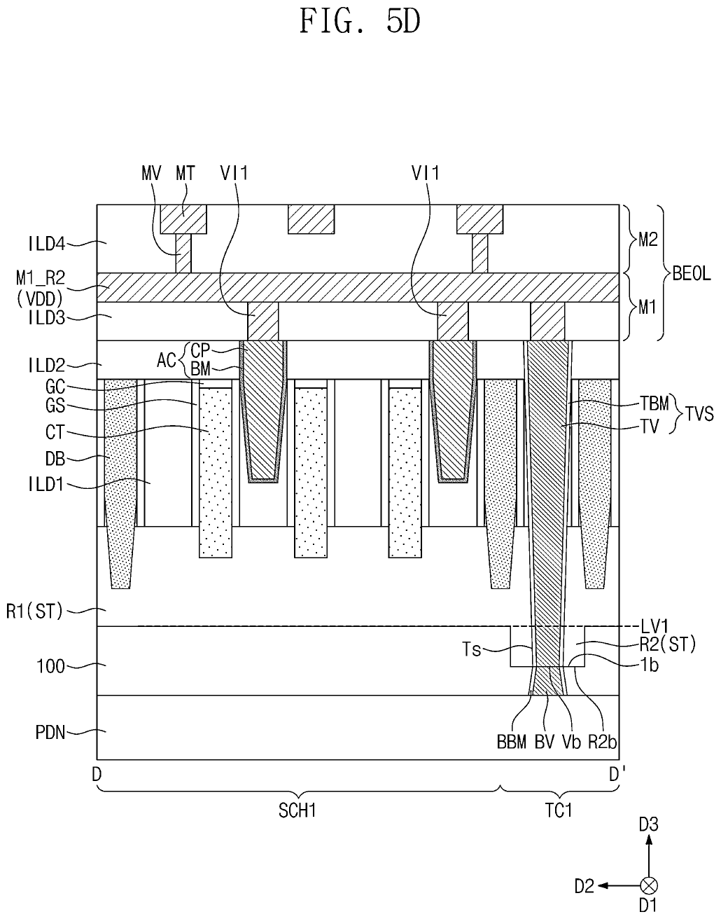

FIG. 4 is a plan view illustrating a semiconductor device according to one or more embodiments. FIGS. 5A-5D are cross-sectional views of the semiconductor device of FIG. 4 taken along lines A-A′, B-B′, C-C′, and D-D′, respectively, shown in FIG. 4. The semiconductor device described with reference to FIGS. 4 and 5A-5D may be an example of or correspond to the semiconductor device of FIG. 3. Thus, the same reference numerals and characters used in the description of the semiconductor device of FIG. 3 may be used herebelow.

Referring to FIGS. 4 and 5A-5D, first and second single height cells SHC1 and SHC2 and first and second tap cells TC1 and TC2 may be provided on a substrate 100. The substrate 100 may be a semiconductor substrate that is formed of or includes silicon, germanium, silicon germanium, a compound semiconductor material, or the like. In one or more embodiments, the substrate 100 may be a silicon wafer. In one or more embodiments, the substrate 100 may be a substrate that is formed of or includes at least one insulating material (e.g., silicon oxide (SiO₂), silicon nitride (SiN), and silicon oxynitride (SiON)). In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements.

The substrate 100 may have the first PMOSFET region PR1, the second PMOSFET region PR2, the first NMOSFET region NR1, and the second NMOSFET region NR2. Each of the PMOSFET and NMOSFET regions PR1, PR2, NR1, and NR2 may be extended in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

Active patterns AP1 and AP2 may be defined by a device isolation trench STR, which is formed in an upper portion of the substrate 100. The active pattern AP1 or AP2 may be a portion of the substrate 100. In one or more embodiments, this portion of the substrate 100 may protrude in a third direction D3. The third direction D3 may be perpendicular to the top or bottom surface of the substrate 100. In the present specification, for convenience of explanation, the substrate 100 may be referred to as the remaining portion of the substrate 100 which does not include the active pattern AP1 or AP2, unless otherwise specified. The substrate 100 and the active pattern AP1 or AP2 may be distinguished from each other, without an interfacial surface therebetween, at a first level LV1. The active pattern AP1 or AP2 may include a first active pattern AP1 provided on the PMOSFET region PR1 and a second active pattern AP2 provided on the NMOSFET region NR1. The first and second active patterns AP1 and AP2 may be extended in the second direction D2.

A substrate recess SRS may be located at a level lower than the device isolation trench STR. The substrate recess SRS may be provided in at least one of the tap cells TC1 and TC2. The substrate recess SRS may be vertically overlapped with the penetration via structure TVS, which will be described below. In one or more embodiments, when viewed in a plan view, the substrate recess SRS may be provided between the first active pattern AP1 of the first tap cell TC1 and the first active pattern AP1 of the second tap cell TC2 but may not be provided between the first and second active patterns AP1 and AP2 of the first tap cell TC1. For example, this substrate recess SRS may be formed below and vertically overlapped, in the third direction D3, by a boundary between the tap cells TC1 and TC2.

In one or more embodiments, a plurality of substrate recesses SRS may be provided in an upper portion of the substrate 100. The substrate recesses SRS may be disposed to be adjacent to each other in the first direction D1. For example, another substrate recess SRS may be formed below and vertically overlapped, in the third direction D3, by another boundary of the tap cell TC1, and still another substrate recess SRS may be formed below and vertically overlapped, in the third direction D3, by another boundary of the tap cell TC2. However, the disclosure is not limited thereto. The arrangement of the substrate recesses SRS may be changed depending on the arrangement of penetration via structures TVS, which will be described below. The substrate recess SRS of FIG. 4 is illustrated to have a rectangular shape when viewed in a plan view, but the disclosure is not limited to this example. The shape of the substrate recess SRS may be variously changed, when viewed in a plan view.

Due to the presence of the device isolation trench STR and the substrate recess SRS, the substrate 100 may have a stepwise structure. For example, the substrate 100 may have top surfaces which are located at different levels. The substrate 100 may have a first top surface 1a on an inner bottom surface of the device isolation trench STR and a second top surface 1b on the inner bottom surface of the substrate recess SRS. The first top surface 1a of the substrate 100 may be located at a level higher than the second top surface 1b of the substrate 100.

A device isolation pattern ST may fill the device isolation trench STR and the substrate recess SRS. The device isolation pattern ST may include an insulating material. In one or more embodiments, the device isolation pattern ST may include a single layer or a composite layer. The device isolation pattern ST may be formed of or include silicon oxide (e.g., SiO₂).

The device isolation pattern ST may include a first region R1, which is provided to enclose the active patterns AP1 and AP2, and a second region R2, which is provided in the substrate recess SRS. The first region R1 of the device isolation pattern ST may be located at a level higher than the first level LV1, and the second region R2 may be located at a level lower than the first level LV1. A bottom surface of the first region R1 of the device isolation pattern ST may be in contact with the first top surface 1a of the substrate 100, and a bottom surface R2b of the second region R2 may be in contact with the second top surface 1b of the substrate 100.

A first channel structure CH1 may be provided on the first active pattern AP1. A second channel structure CH2 may be provided on the second active pattern AP2. Each of the first and second channel structures CH1 and CH2 may include a first semiconductor pattern SP1, a second semiconductor pattern SP2, and a third semiconductor pattern SP3, which are adjacent to each other in the third direction D3, but the disclosure is not limited to this example. In one or more embodiments, each of the first and second channel structures CH1 and CH2 may include four or more semiconductor patterns. In one or more embodiments, each of the first to third semiconductor patterns SP1, SP2, and SP3 may be formed of or include crystalline silicon.

First recesses RS1 may be defined between the first channel structures CH1, which are adjacent to each other in the second direction D2. Second recesses RS2 may be defined between the second channel structures CH2, which are adjacent to each other in the second direction D2.

A first source/drain pattern SD1 may be provided on the first active pattern AP1, and a second source/drain pattern SD2 may be provided on the second active pattern AP2. The first source/drain pattern SD1 may fill the first recess RS1, and the second source/drain pattern SD2 may fill the second recess RS2. Each of the first and second source/drain patterns SD1 and SD2 may be electrically connected to the first to third semiconductor patterns SP1, SP2, and SP3. The first source/drain patterns SD1 may be impurity regions having a first conductivity type (e.g., p-type), and the second source/drain patterns SD2 may be impurity regions having a second conductivity type (e.g., n-type). In one or more embodiments, a pair of the first source/drain patterns SD1 may be electrically connected to each other through the first channel structure CH1. A pair of the second source/drain patterns SD2 may be electrically connected to each other through the second channel structure CH2.

The first source/drain patterns SD1 may be formed of or include a semiconductor material (e.g., SiGe) whose lattice constant is greater than that of the first channel structure CH1. In this case, the pair of the first source/drain patterns SD1 may exert a compressive stress on the first channel structure CH1 therebetween. The second source/drain patterns SD2 may be formed of or include the same semiconductor material (e.g., Si) as the second channel structure CH2.

The first source/drain pattern SD1 may include a buffer layer BFL covering an inner surface of the first recess RS1 and a main layer MAL filling most of a remaining portion of the first recess RS1. In one or more embodiments, each of the buffer and main layers BFL and MAL may be formed of or include silicon germanium (SiGe). The buffer layer BFL may contain a relatively low concentration of germanium (Ge). The main layer MAL may contain a relatively high concentration of germanium. In one or more embodiments, the buffer layer BFL may contain only silicon (Si).

A gate electrode GE may be provided on the first and second channel structures CH1 and CH2 to cross the first and second channel structures CH1 and CH2. In one or more embodiments, a plurality of gate electrodes GE may be provided. The gate electrodes GE may be extended in the first direction D1 and may be spaced apart from each other in the second direction D2.

The gate electrode GE may include an inner electrode and an outer electrode. The inner electrode of the gate electrode GE may be provided between the uppermost one of the semiconductor patterns SP1, SP2, and SP3 and the active pattern AP1 or AP2. The outer electrode of the gate electrode GE may be provided on the uppermost one of the semiconductor patterns. The inner electrode of the gate electrode GE may include a first electrode portion EP1, a second electrode portion EP2, and a third electrode portion EP3, but the disclosure is not limited to this example. As an example, the inner electrode of the gate electrode GE may include four or more electrode portions depending on the number of the semiconductor patterns. The first electrode portion EP1 may be interposed between the active pattern AP1 or AP2 and the first semiconductor pattern SP1. The second electrode portion EP2 may be interposed between the first semiconductor pattern SP1 and the second semiconductor pattern SP2. The third electrode portion EP3 may be interposed between the second semiconductor pattern SP2 and the third semiconductor pattern SP3. In one or more embodiments, the outer electrode of the gate electrode GE may include a fourth electrode portion EP4. The fourth electrode portion EP4 may be provided on the third semiconductor pattern SP3.

The gate electrode GE may include a first metal pattern and a second metal pattern on the first metal pattern. The first metal pattern may include a work-function metal, which can be used to adjust a threshold voltage of a transistor. In one or more embodiments, the first metal pattern may be formed of or include at least one of metallic materials (e.g., Ti, Mo, W, Cu, Al, Ta, Ru, Ir, and Co) and metal nitride materials (e.g., nitrides of Ti, Mo, W, Cu, Al, Ta, Ru, Ir, and Co). In one or more embodiments, the first metal pattern may further include carbon (C). The first metal pattern may be formed of or include at least one of metallic materials having different work functions.

In one or more embodiments, the second metal pattern may be formed of or include at least one of metallic materials (e.g., Ti, Mo, W, Cu, Al, Ta, Ru, Ir, and Co) whose electric resistances are lower than that of the first metal pattern.

The first to third electrode portions EP1, EP2, and EP3 of the gate electrode GE may include a first metal pattern. In one or more embodiments, the fourth electrode portion EP4 of the gate electrode GE may include the first metal pattern and the second metal pattern.

Gate cutting patterns CT may be provided on boundaries between the first and second single height cells SHC1 and SHC2. The gate electrode GE on the first single height cell SHC1 may be separated from the gate electrode GE on the second single height cell SHC2 by the gate cutting pattern CT. The gate cutting patterns CT may include an insulating material.

A gate capping pattern GC may be provided on a top surface of the gate electrode GE. In one or more embodiments, the gate capping pattern GC may be formed of or include at least one of SiON, SiCN, SiOCN, or SiN.

The gate spacers GS may be provided on side surfaces of the fourth electrode portion EP4 of the gate electrode GE and may be extended along respective side surfaces of the gate capping pattern GC. The gate spacer GS may include a single layer or a composite layer. In one or more embodiments, the gate spacer GS may be formed of or include at least one of SiON, SiCN, SiOCN, or SiN.

A gate insulating pattern GI may be interposed between the gate electrode GE and the first to third semiconductor patterns SP1, SP2, and SP3. The gate insulating pattern GI may cover top, bottom, and opposite side surfaces of each of the first to third semiconductor patterns SP1, SP2, and SP3. The gate insulating pattern GI may be disposed on a top surface of the second region R2 of the device isolation pattern ST below the gate electrode GE. The gate insulating pattern GI may be interposed between a fourth electrode portion EP and the gate spacer GS. The gate insulating pattern GI may be formed of or include at least one of silicon oxide (SiO₂), silicon oxynitride (SiON), or high-k dielectric materials. In the present specification, the high-k dielectric material may be defined as a material having a dielectric constant higher than silicon oxide.

An inner spacer ISP may be interposed between the second source/drain pattern SD2 and a side surface of the gate electrode GE. In one or more embodiments, the inner spacer ISP may be interposed between the inner electrode and the second source/drain pattern SD2. The inner spacer ISP may include an insulating material.

A first interlayer insulating layer ILD1 may be provided on the substrate 100. The first interlayer insulating layer ILD1 may be disposed on the gate spacers GS and the first and second source/drain patterns SD1 and SD2. A top surface of the first interlayer insulating layer ILD1 may be located at substantially the same level as a top surface of the gate capping pattern GC and a top surface of the gate spacer GS.

A second interlayer insulating layer ILD2 may be provided on the first interlayer insulating layer ILD1 to isolate the gate capping pattern GC. A third interlayer insulating layer ILD3 may be provided on the second interlayer insulating layer ILD2. A fourth interlayer insulating layer ILD4 may be provided on the third interlayer insulating layer ILD3. In one or more embodiments, the first to fourth interlayer insulating layers ILD1, ILD2, ILD3, and ILD4 may be formed of or include silicon oxide (e.g., SiO₂).

Division structures DB may be formed on boundaries between cells. In one or more embodiments, the first division structure DB1 may be provided between the first and second single height cells SHC1 and SHC2 and the first and second tap cells TC1 and TC2. The second division structure DB2 may be provided between the first and second tap cells TC1 and TC2 and other logic cells adjacent thereto. Each of the first and second tap cells TC1 and TC2 may be provided between a pair of division structures DB1 and DB2.

The division structure DB may be extended in the first direction D1. The division structure DB may penetrate the first and second interlayer insulating layers ILD1 and ILD2 and may be extended into the first and second active patterns AP1 and AP2.

An active contact AC may penetrate the first and second interlayer insulating layers ILD1 and ILD2 and may be electrically connected to the source/drain pattern SD1 or SD2. In one or more embodiments, a plurality of active contacts AC may be provided, and a lower portion of each of the active contacts AC may be buried in an upper portion of a corresponding one of the source/drain patterns SD1 and SD2.

An ohmic pattern OM may be interposed between the active contact AC and the source/drain pattern SD1 or SD2 corresponding thereto. Accordingly, it may be possible to improve a contact resistance between the active contact AC and the source/drain pattern SD1 or SD2. In one or more embodiments, the ohmic pattern OM may be formed of or include at least one of metal silicide materials (e.g., silicide materials containing Ti, Mo, W, Cu, Al, Ta, Ru, and Ir).

A gate contact GT may penetrate the second interlayer insulating layer ILD2 and the gate capping pattern GC and may be electrically connected to the gate electrode GE. In one or more embodiments, a plurality of gate contacts GT may be provided, and each of the gate contacts GT may be freely formed on a corresponding one of the gate electrodes GE, without any limitation in its position.

Each of the active and gate contacts AC and GC may include a conductive pattern CP and a barrier pattern BM enclosing the conductive pattern CP. The conductive pattern CP may be formed of or include at least one of metallic materials (e.g., Ti, Mo, W, Cu, Al, Ta, Ru, Ir, and Co). In one or more embodiments, the barrier pattern BM may be formed of or include at least one of metal nitride materials (e.g., nitrides of Ti, Mo, W, Cu, Al, Ta, Ru, Ir, and Co).

A first interconnection layer M1 may be provided in the third interlayer insulating layer ILD3. The first interconnection layer M1 may include first interconnection lines M1_1, the first to third power lines M1_R1, M1_R2, and M1_R3, and first vias VI1 thereunder. The first interconnection lines M1_1 and the first to third power lines M1_R1, M1_R2, and M1_R3 may be extended in the second direction D2. The first interconnection line M1_1 may be electrically connected to the active and gate contacts AC and GT through the first vias VI1. The second power line M1_R2 may be electrically connected to at least one active contact AC through the first via VI1.

The penetration via structure TVS may be provided in the first and second tap cells TC1 and TC2. The penetration via structure TVS may electrically connect each of the first to third power lines M1_R1, M1_R2, and M1_R3 to a power delivery network layer PDN to be described below. The penetration via structure TVS may be electrically connected to each of the first to third power lines M1_R1, M1_R2, and M1_R3 through the first via VI1.

The penetration via structure TVS may be provided to penetrate the first and second interlayer insulating layers ILD1 and ILD2 and may be extended into the substrate recess SRS in the third direction D3. The penetration via structure TVS may be vertically overlapped with the substrate recess SRS. A bottom surface Vb of the penetration via structure TVS may be substantially coplanar with an inner bottom surface of the substrate recess SRS. In one or more embodiments, the bottom surface Vb of the penetration via structure TVS may be substantially coplanar with the second top surface 1b of the substrate 100. As an example, the penetration via structure TVS may not be extended into a region of the substrate 100, which is vertically overlapped with the substrate recess SRS.

At the first level LV1 and at a level lower than the first level LV1, a width of the penetration via structure TVS may be smaller than a width of the substrate recess SRS. Here, the widths may be measured in a direction that is parallel to the top or bottom surface of the substrate 100, e.g., the first direction D1 or the second direction D2. At the first level LV1, a distance between the penetration via structure TVS and the first active pattern AP1, which are adjacent to each other, may be larger than a distance between the penetration via structure TVS and an inner side surface of the substrate recess SRS corresponding to the penetration via structure TVS.

The penetration via structure TVS may be extended into the substrate recess SRS to penetrate each of the first and second regions R1 and R2 of the device isolation pattern ST. The second region R2 of the device isolation pattern ST may be interposed between the penetration via structure TVS and the substrate 100. A side surface Ts of the penetration via structure TVS may be spaced apart from the inner side surface of the substrate recess SRS by the second region R2 of the device isolation pattern ST. The bottom surface Vb of the penetration via structure TVS may be substantially coplanar with the bottom surface R2b of the second region R2 of the device isolation pattern ST.

The penetration via structure TVS may include a penetration via pattern TV and a penetration barrier pattern TBM enclosing the penetration via pattern TV. The penetration via pattern TV of the penetration via structure TVS may electrically connect each of the first to third power lines M1_R1, M1_R2, and M1_R3 to the power delivery network layer PDN to be described below. A width of the penetration via pattern TV, in a direction parallel to the top or bottom surface of the substrate 100, may increase as a height in the third direction D3 increases. The bottom surface Vb of the penetration via structure TVS described above may be a bottom surface of the penetration via pattern TV, and the side surface Ts of the penetration via structure TVS may be a side surface of the penetration barrier pattern TBM. This is because the penetration barrier pattern TBM may be omitted depending on a process of fabricating the penetration via structure TVS and/or a material forming the penetration via pattern TV, according to one or more embodiments.

In one or more embodiments, the penetration via pattern TV may be formed of or include at least one of metallic materials (e.g., Ti, Mo, W, Cu, Al, Ta, Ru, Ir, and Co). The penetration barrier pattern TBM may be formed of or include at least one of metal nitride materials (e.g., nitrides of Ti, Mo, W, Cu, Al, Ta, Ru, Ir, and Co).

The power delivery network layer PDN may be provided on or below the bottom surface of the substrate 100 in the third direction D3. The power delivery network layer PDN may include a plurality of lower interconnection lines, which are electrically connected to the first to third power lines M1_R1, M1_R2, and M1_R3. The power delivery network layer PDN may include an interconnection network, which is used to apply the source voltage VSS to the first and third power lines M1_R1 and M1_R3. In one or more embodiments, the power delivery network layer PDN may include an interconnection network, which is used to apply a second voltage VDD to the second power line M1_R2.

A backside via pattern BV may be interposed between the penetration via structure TVS and the power delivery network layer PDN. The penetration via structure TVS may be electrically connected to the power delivery network layer PDN through the backside via pattern BV. A width of the backside via pattern BV, a direction parallel to the bottom surface of the substrate 100, may decrease as a height in the third direction D3 increases. A top surface of the backside via pattern BV may be in contact with the bottom surface of the penetration via pattern TV. The top surface of the backside via pattern BV may be substantially coplanar with the second top surface 1b of the substrate 100. In one or more embodiments, the backside via pattern BV may be formed of or include at least one of metallic materials (e.g., Ti, Mo, W, Cu, Al, Ta, Ru, Ir, and Co).

A backside barrier pattern BBM may be provided to enclose a side surface of the backside via pattern BV. The backside barrier pattern BBM may be formed of or include at least one of metal nitride materials (e.g., nitrides of Ti, Mo, W, Cu, Al, Ta, Ru, Ir, and Co). However, the backside barrier pattern BBM may be omitted depending on a process of fabricating the backside via pattern BV and/or a material forming the backside via pattern BV, according to one or more embodiments.

A second interconnection layer M2 may be provided in the fourth interlayer insulating layer ILD4. The second interconnection layer M2 may include metal patterns MT and metal vias MV below the metal patterns MT. The metal patterns MT may be electrically connected to the first interconnection layer M1 through the metal vias MV. In one or more embodiments, a plurality of metal patterns MT and a plurality of metal vias MV may be alternatively stacked. The metal patterns MT and vias VI may be formed of or include at least one of metallic materials (e.g., Ti, Mo, W, Cu, Al, Ta, Ru, Ir, and Co).

The first and second interconnection layers M1 and M2 may form a back-end-of-line (BEOL) structure. The BEOL structure may include interconnection lines, which are used as routing paths between cells.

Herein, the substrate recesses SRS and the penetration via structures TVS may be formed in the tap cells TC1 and TC2 in which the first and second source/drain regions SD1 and SD2 are not connected to any interconnection layer for signal routing or power delivery through, for example, the power lines M1_R1, M1_R2 and M1_R2. The first and second source/drain regions SD1 and SD2 may also not be connected to the first and second channel structures CH1 and CH2. Thus, the tap cells TC1 and TC2 may be dummy cells having far less signal routing traffic, so that the formation of the penetration via structures TVS may be facilitated in the tap cells TC1 and TC2.

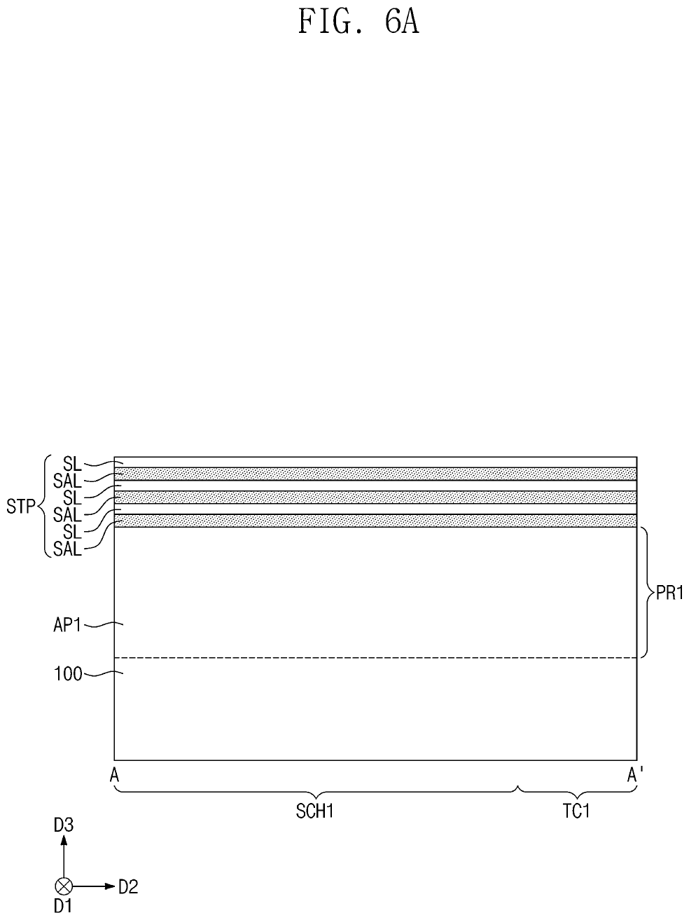

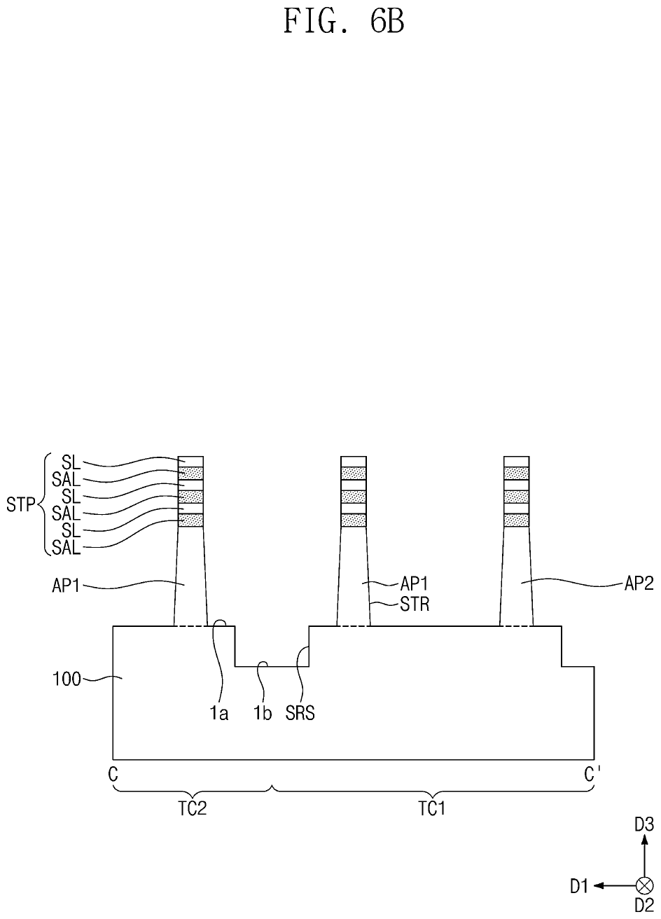

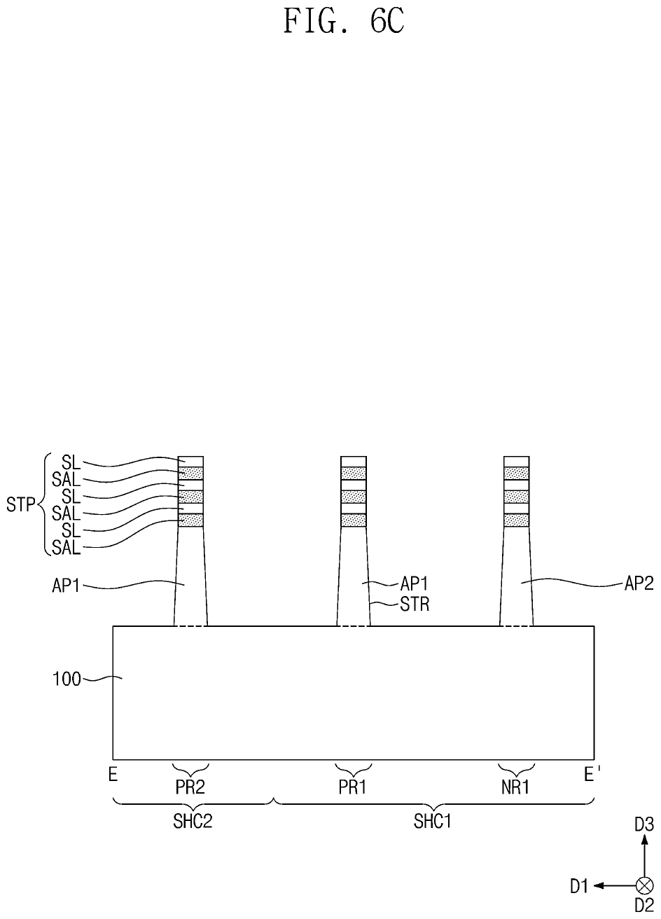

Hereinafter, a method of fabricating a semiconductor device according to one or more embodiments will be described in more detail with reference to FIGS. 6A to 12. In the following description, a previously-described element may be identified by the same reference number without repeating an overlapping description thereof, for concise description.

FIGS. 6A to 13 are cross-sectional views illustrating a method of fabricating a semiconductor device, according to one or more embodiments. It is to be understood herebelow that the semiconductor device fabricated through the method in reference to the cross-sectional views of FIGS. 6A to 13 may be or correspond to the semiconductor device shown in FIGS. 4 and 5A-5D, and thus the cross-section directions A-A′, B-B′, C-C′, D-D′ and E-E′ shown in FIGS. 6A to 13 correspond to those shown in FIG. 4.

Referring to FIGS. 4 and 6A to 6C, the substrate 100 including the first and second PMOSFET regions PR1 and PR2 and the first and second NMOSFET regions NR1 and NR2 may be provided. Stacking patterns STP may be formed on the first and second PMOSFET regions PR1 and PR2 and the first and second NMOSFET regions NR1 and NR2. In one or more embodiments, the formation of the stacking patterns STP may include alternatingly stacking semiconductor layers SL and sacrificial layers SAL on the substrate 100, forming mask patterns (not shown) extending in the first direction D1, and performing a patterning process using the mask patterns as an etch mask. The sacrificial layers SAL may include a material having an etch selectivity with respect to the semiconductor layers SL. Thus, the semiconductor layers SL may not be substantially removed in a subsequent process of removing the sacrificial layers SAL. The semiconductor and sacrificial layers SL and SAL may be formed of or include at least one of silicon (Si), germanium (Ge), or silicon germanium (SiGe), but the material of the sacrificial layers SAL may be different from that of the semiconductor layers SL.

When the patterning process is performed to form the stacking patterns STP, a portion of the substrate 100 may be etched to form the device isolation trenches STR defining the first active pattern AP1 and the second active pattern AP2.

After the process of forming the stacking patterns STP, a removal process may be performed on an upper portion of the substrate 100, and as a result, the substrate recesses SRS may be formed in the upper portion of the substrate 100. In one or more embodiments, the substrate 100 may have the first and second top surfaces 1a and 1b, which are formed at different levels.

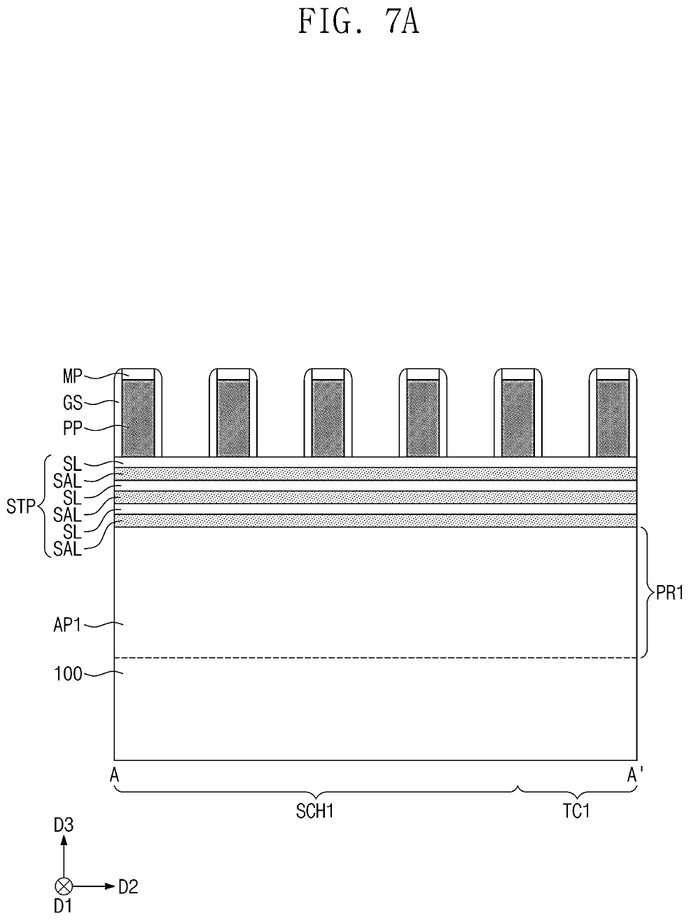

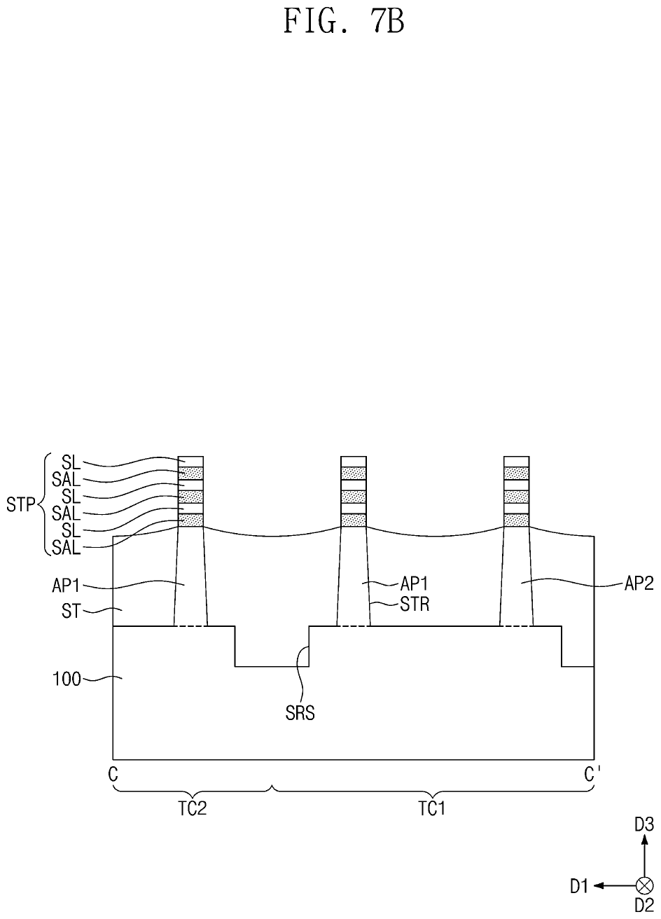

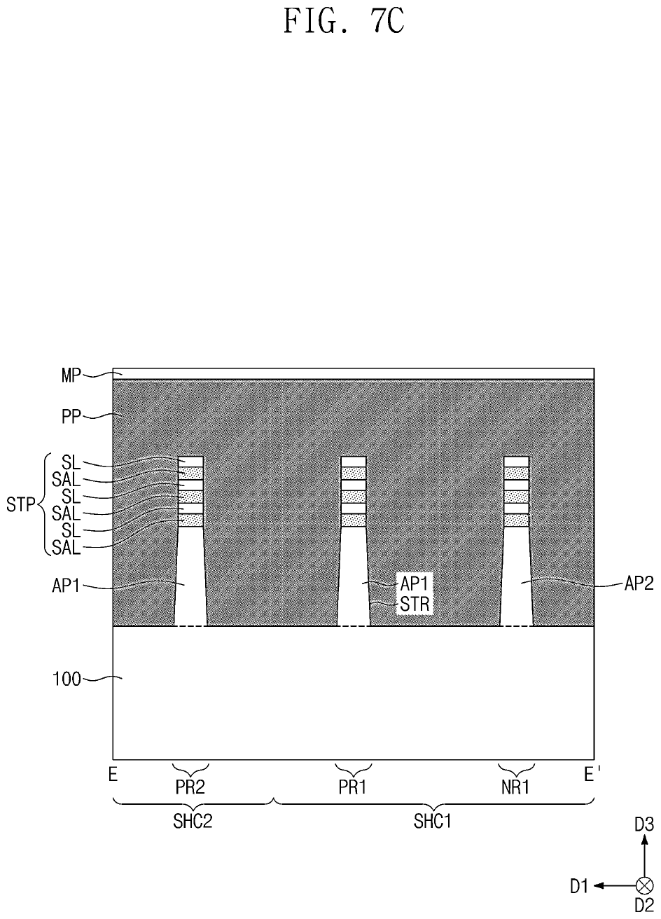

Referring to FIGS. 4 and 7A to 7C, the device isolation pattern ST may be formed to fill the device isolation trench STR and the substrate recess SRS. Sacrificial patterns PP may be formed on the substrate 100 and may be extended in the first direction D1. The sacrificial patterns PP may be formed on the top surfaces of the device isolation patterns ST and the side and top surfaces of the stacking patterns STP. In one or more embodiments, the formation of the sacrificial patterns PP may include forming a sacrificial layer (not shown) on the substrate 100, forming hard mask patterns MP on the sacrificial layer, and forming the sacrificial patterns PP by removing a portion of the sacrificial layer using the hard mask patterns MP as an etch mask. In one or more embodiments, the sacrificial pattern PP may be formed of or include polysilicon. Next, the gate spacers GS may be formed on a side surface of the sacrificial patterns PP.

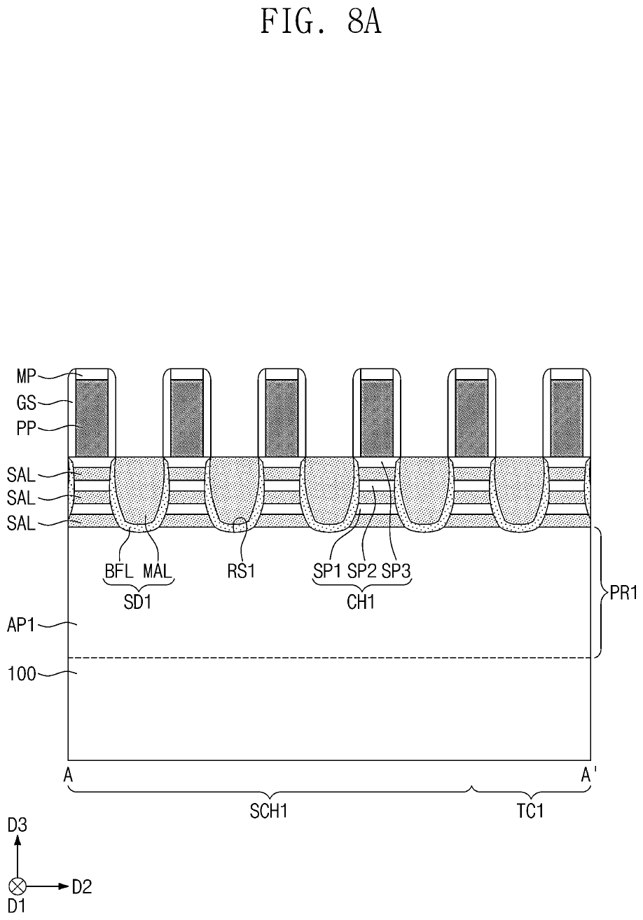

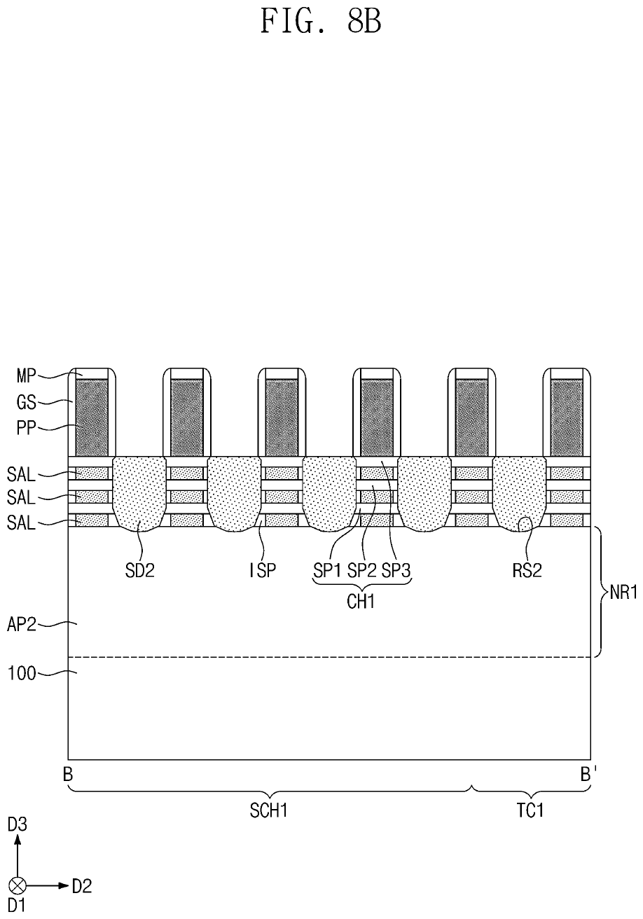

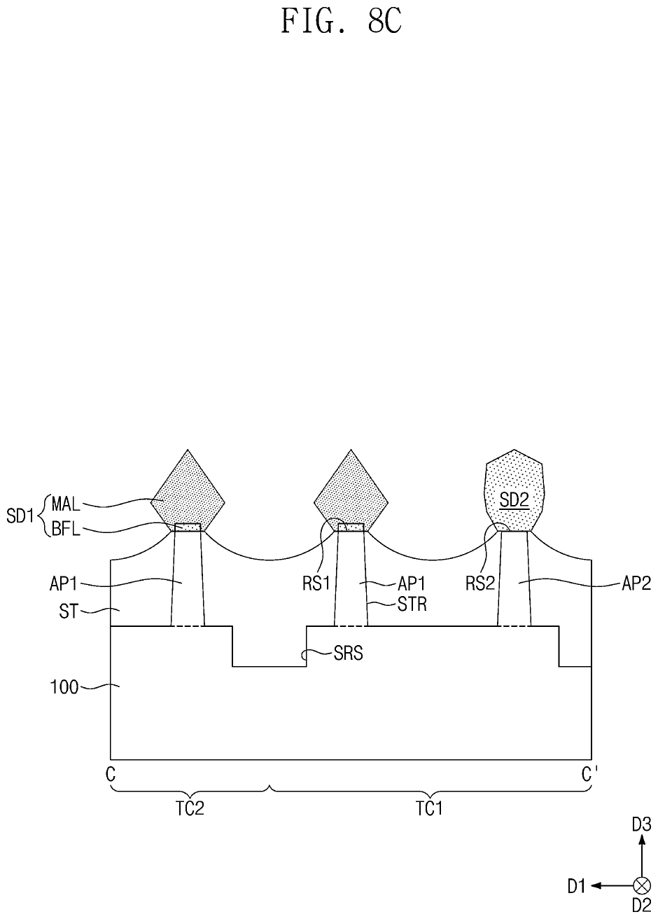

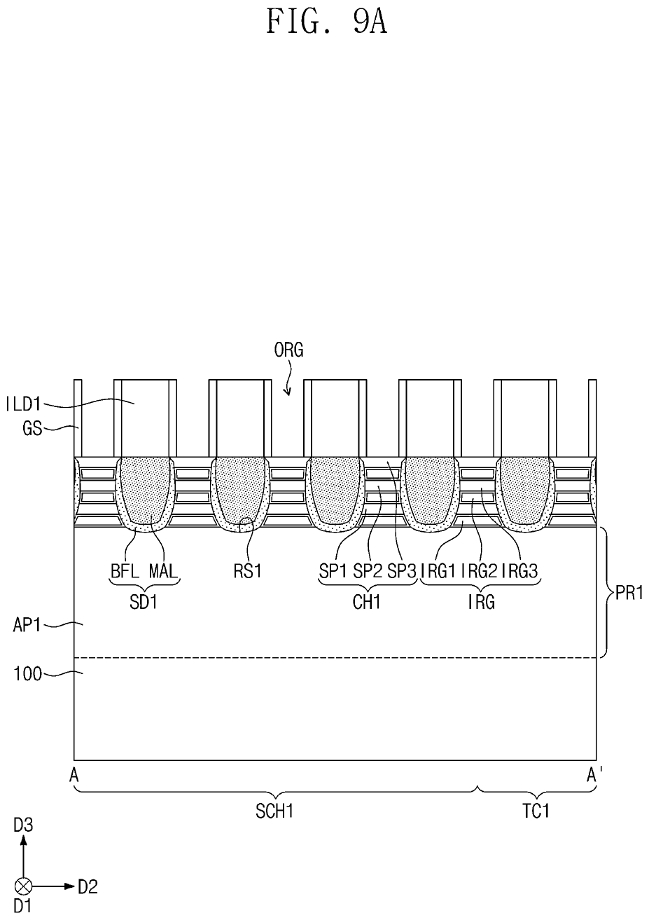

Referring to FIGS. 4 and 8A to 8C, the first recesses RS1 may be formed in the stacking pattern STP on the first active pattern AP1. The second recesses RS2 may be formed in the stacking pattern STP on the second active pattern AP2. As an example, the first and second recesses RS1 and RS2 may be formed by removing a portion of the stacking pattern STP using the hard mask patterns MP and the gate spaces GS as an etch mask.

The semiconductor layers SL on the first active pattern AP1 may be divided into the first channel structures CH1, which are spaced apart from each other in the first direction D1, by the first recesses RS1. The semiconductor layers SL on the second active pattern AP2 may be divided into the second channel structures CH2, which are spaced apart from each other in the first direction D1, by the second recesses RS2. Each of the first and second channel structures CH1 and CH2 may include the first to third semiconductor patterns SP1, SP2, and SP3.

A portion of the sacrificial layer SAL exposed through the second recess RS2 may be replaced with an insulating material, and as a result, inner spacers ISP may be formed on opposite side surfaces of the sacrificial layer SAL.

The first source/drain patterns SD1 may be formed in the first recesses RS1. In one or more embodiments, the formation of the first source/drain pattern SD1 may include forming the buffer layer BFL through a selective epitaxial growth (SEG) process using the first to third semiconductor patterns SP1, SP2, and SP3 on the PMOSFET region PR1 or PR2 and the substrate 100 as a seed layer and forming the main layer MAL through a SEG process using the buffer layer BFL as a seed layer.

In one or more embodiments, during the formation of the first source/drain pattern SD1, p-type impurities (e.g., boron, gallium, or indium) may be injected into the first source/drain pattern SD1 in an in-situ doping manner. In another embodiment, the impurities may be injected into the first source/drain pattern SD1, after the formation of the first source/drain pattern SD1.

The second source/drain patterns SD2 may be formed in the second recesses RS2. The second source/drain patterns SD2 may be formed through an SEG process using the first to third semiconductor patterns SP1, SP2, and SP3 on the NMOSFET region NR1 or NR2 and the substrate 100 as a seed layer.

In one or more embodiments, during the formation of the second source/drain pattern SD2, n-type impurities (e.g., phosphorus, arsenic, or antimony) may be injected into the second source/drain pattern SD2 in an in-situ doping manner. In another embodiment, the impurities may be injected into the second source/drain pattern SD2 after the formation of the second source/drain pattern SD2.

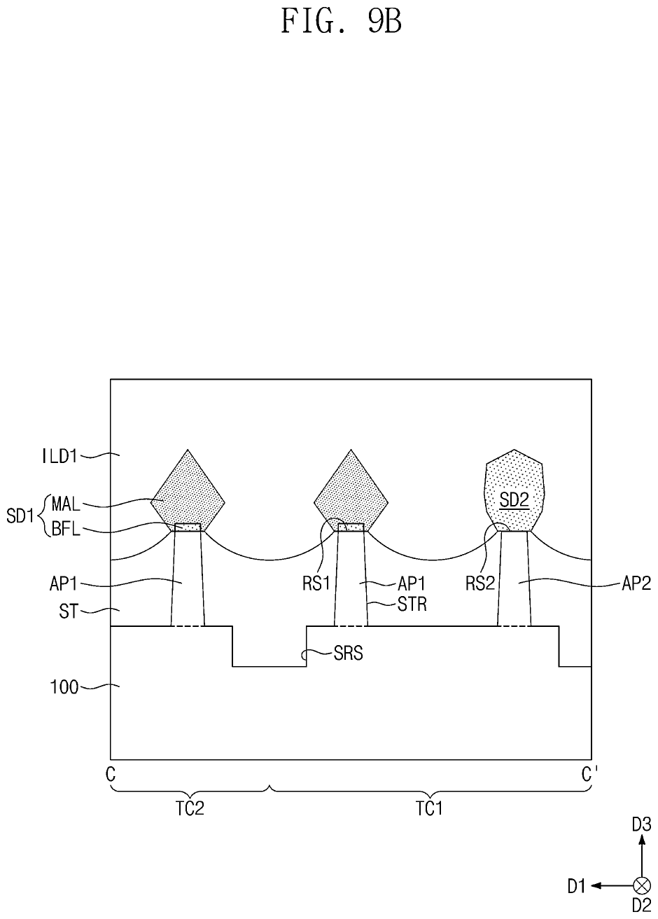

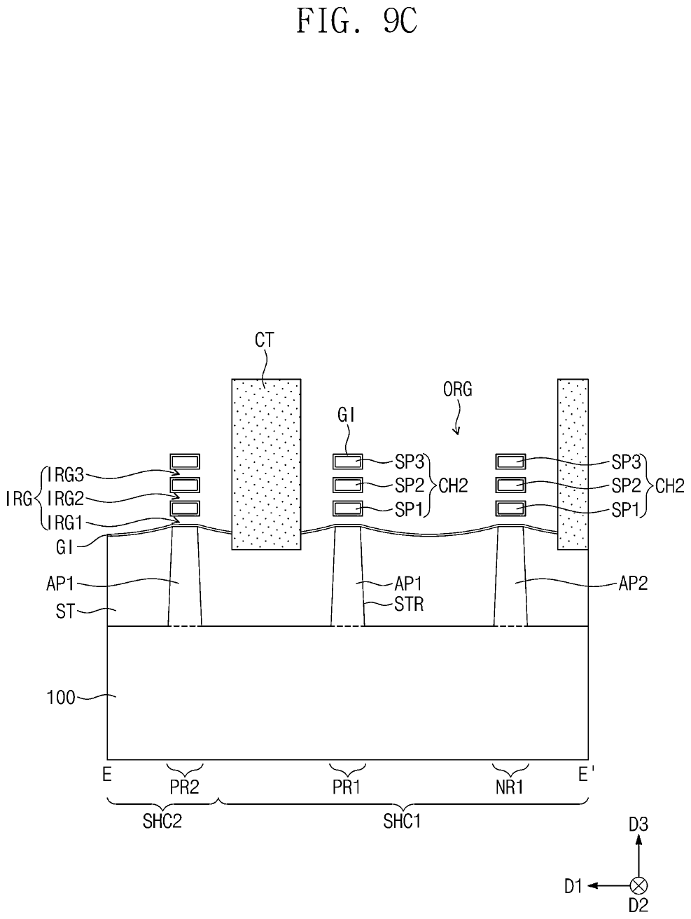

Referring to FIGS. 4 and 9A to 9C, the first interlayer insulating layer ILD1 may be formed on the first and second source/drain patterns SD1 and SD2, the hard mask patterns MP, and the gate spacers GS. Thereafter, the first interlayer insulating layer ILD may be removed from top surfaces of the sacrificial patterns PP. In one or more embodiments, the hard mask patterns MP may be removed by the process of removing the first interlayer insulating layer ILD, and as a result, the sacrificial patterns PP may be exposed to the outside.

Thereafter, the exposed sacrificial patterns PP may be removed to form an outer region ORG as an empty region. The first and second channel structures CH1 and CH2 and the sacrificial layers SAL may be exposed to the outside through the outer region ORG.

Next, the exposed sacrificial layers SAL may be selectively removed. Here, the first to third semiconductor patterns SP1, SP2, and SP3 may be hardly or less removed, due to high etch selectivity of the sacrificial layers SAL.

Inner regions IRG may be empty regions which are formed by removing the sacrificial layers SAL. The inner regions IRG may be formed between the first to third semiconductor patterns SP1, SP2, and SP3. The inner regions IRG may include first to third inner regions IRG1, IRG2, and IRG3, which are spaced apart from each other in the third direction D3.

The gate insulating pattern GI may be formed in each of the inner regions IRG and the outer region ORG. The gate insulating pattern GI may be formed to enclose each of the first to third semiconductor patterns SP1, SP2, and SP3.

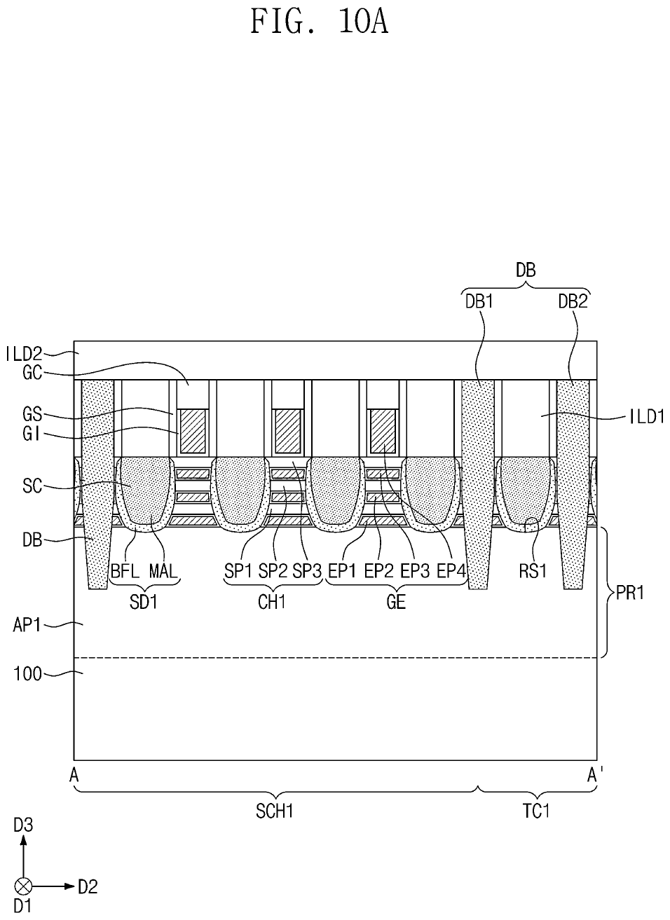

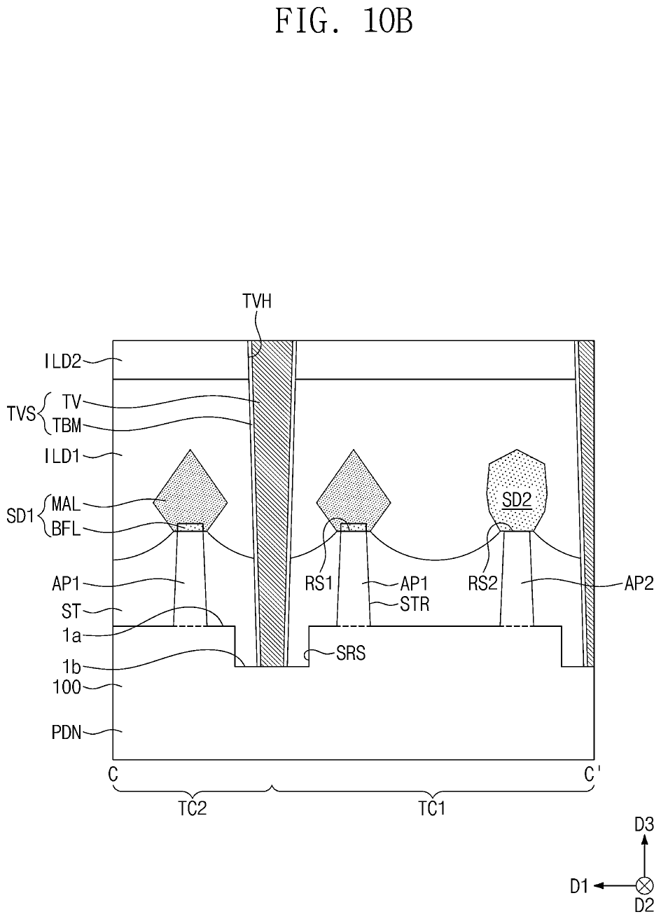

Referring to FIGS. 4, 10A, and 10B, the gate electrode GE may be formed on the gate insulating pattern GI. The gate electrode GE may include inner electrodes (e.g., the first to third electrode portions EP1, EP2, and EP3), which are respectively formed in the first to third inner regions IRG1, IRG2, and IRG3, and an outer electrode (e.g., the fourth electrode portion EP4), which is formed in the outer region ORG. Thereafter, the gate capping pattern GC may be formed on the fourth electrode portion EP4.

The gate cutting pattern CT may be formed to penetrate the gate electrode GE. Accordingly, the gate electrode GE, which is extended in the first direction D1, may be divided into a plurality of gate electrodes GE, which are adjacent to each other in the first direction D1.

The division structure DB may be formed on a boundary between the cells. The division structure DB may be formed to penetrate the gate electrode GE and extend into the active pattern AP1 or AP2.

The second interlayer insulating layer ILD2 may be formed on the first interlayer insulating layer ILD1 and the gate capping pattern GC.

Penetration holes TVH may be formed in the substrate recess SRS. The penetration holes TVH may be formed to penetrate the first and second interlayer insulating layers ILD1 and ILD2 and the first and second regions R1 and R2 of the device isolation pattern ST and extend into the substrate recess SRS. The penetration hole TVH may be vertically overlapped with the substrate recess SRS. Accordingly, the second top surface 1b of the substrate 100 may be exposed through the penetration hole TVH.

According to one or more embodiments, the substrate recess SRS may be formed in an upper portion of the substrate 100, and the penetration hole TVH, which is extended into the substrate recess SRS, may be formed to penetrate neighboring elements (e.g., the first and second interlayer insulating layers ILD1 and ILD2 and the device isolation pattern ST), which are formed of or include the same or similar insulating material.

Meanwhile, if the substrate recess SRS is not formed in advance, the penetration hole TVH may be formed by removing the neighboring elements as well as an upper portion of the substrate 100. In this case, the etching processes of removing the neighboring elements and the substrate 100 may be performed under different process conditions. This may increase complexity in the etching process for forming the penetration hole TVH.

In contrast, according to one or more embodiments, the substrate recess SRS may be formed in the upper portion of the substrate 100. Thus, the penetration hole TVH may be formed by removing the neighboring elements, without a subsequent process of etching the substrate 100. This means that it is possible to simplify the etching process for forming the penetration hole TVH. Thus, the productivity of the semiconductor device may be improved.

Furthermore, the neighboring elements may be selectively removed in the etching process for the formation of the penetration hole TVH. For example, it may be possible to prevent or suppress the substrate 100 from being unintentionally removed by the etching process of removing the neighboring elements. Thus, even when the penetration hole TVH is misaligned, it may be possible to prevent or suppress a portion of the substrate 100, which is adjacent to the substrate recess SRS in a horizontal direction, from being unintentionally removed. As a result, a process failure, which is caused by the misalignment of the penetration hole TVH, may be reduced. Thus, the productivity of the semiconductor device may be improved.

The penetration barrier pattern TBM may be formed to on an inner side surface of the penetration hole TVH. The penetration via pattern TV may be formed to fill a remaining portion of the penetration hole TVH.

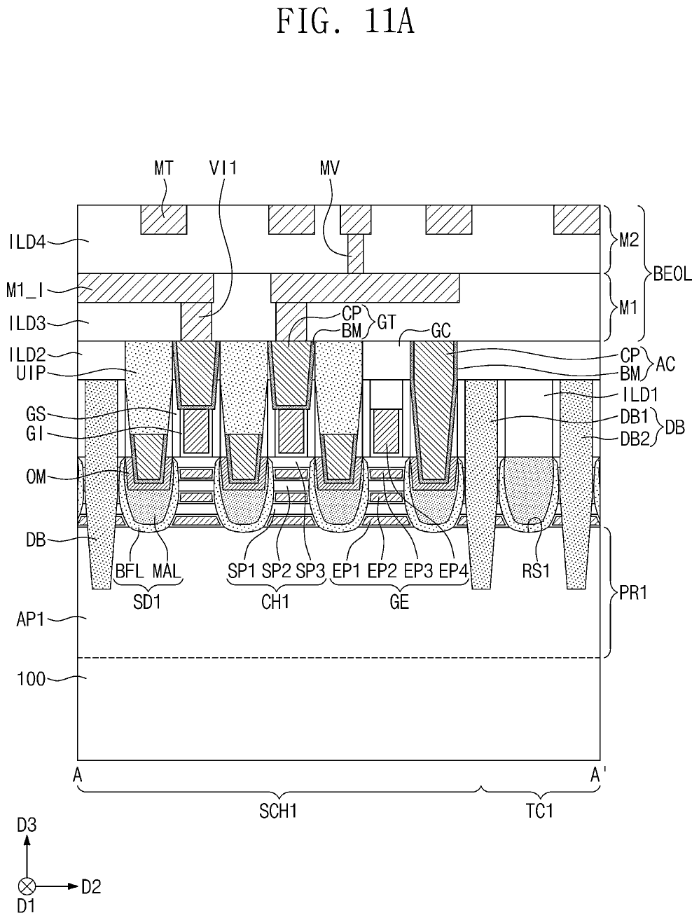

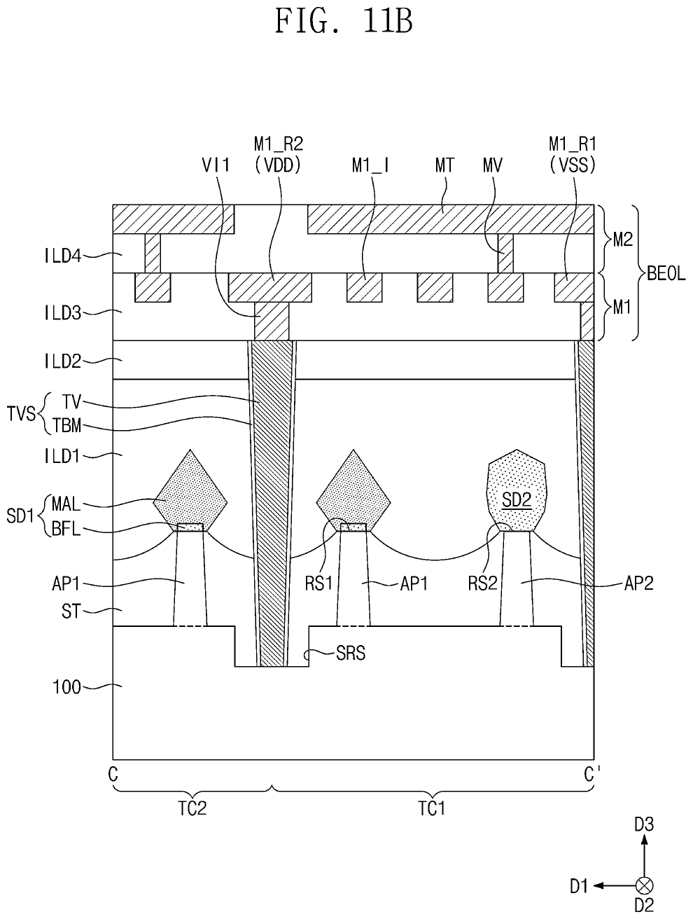

Referring to FIGS. 4, 11A, and 11B, the active contacts AC may be formed to penetrate the first and second interlayer insulating layers ILD1 and ILD2 and to be electrically connected to the first and second source/drain patterns SD1 and SD2. The gate contact GT may be formed to penetrate the second interlayer insulating layer ILD2 and the gate capping pattern GC and to be electrically connected to the gate electrode GE. The third interlayer insulating layer ILD3 may be formed on the second interlayer insulating layer ILD2.

The first interconnection layer M1 may be formed in the third interlayer insulating layer ILD3. The first interconnection layer M1 may be formed to include the first to third power lines M1_R1, M1_R2, and M1_R3, which are electrically connected to the penetration via structures TVS, respectively. The first interconnection layer M1 may be formed to further include a first interconnection M1_I, which is electrically connected to at least one active contact AC or at least one gate contact GT.

The fourth interlayer insulating layer ILD4 may be formed on the third interlayer insulating layer ILD3. The second interconnection layer M2 may be formed in the fourth interlayer insulating layer ILD4. The first and second interconnection layers M1 and M2 may form a BEOL structure.

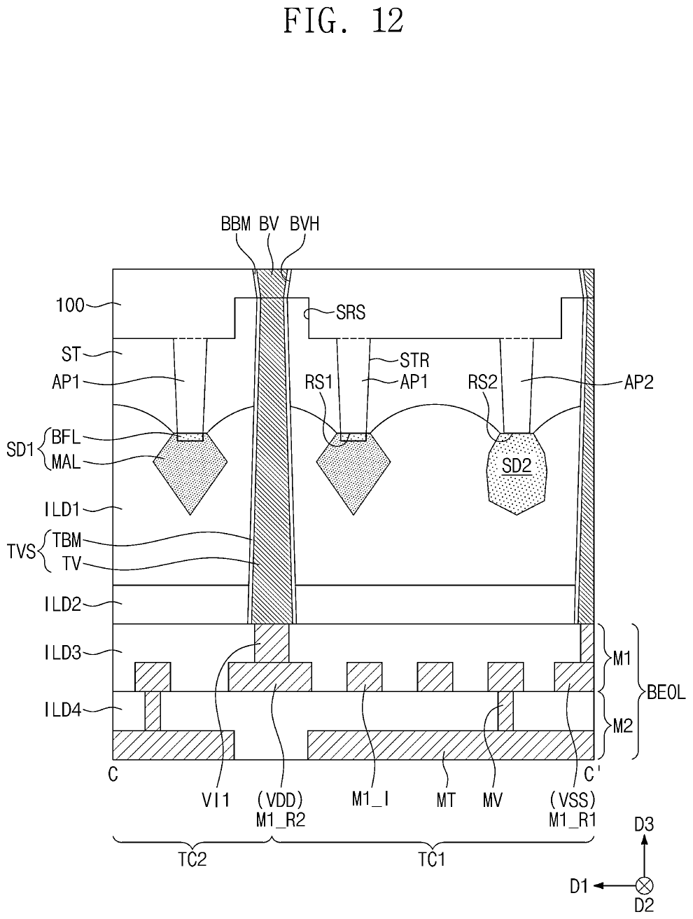

Referring to FIGS. 4 and 12, the substrate 100 may be inverted after a process of forming the BEOL layer. Accordingly, the bottom surface of the substrate 100 may be exposed to the outside. A planarization process may be performed on the bottom surface of the substrate 100 to reduce a thickness of the substrate 100.

A patterning process may be performed on the bottom surface of the substrate 100, and thus, a backside via hole BVH may be formed in the substrate 100. The backside via hole BVH may be formed to be vertically overlapped with the penetration via structure TVS. The backside barrier pattern BBM may be formed on an inner side surface of the backside via hole BVH. The backside via pattern BV may be formed to fill a remaining portion of the backside via pattern BV.

Referring to FIGS. 4 and 5A-5D, the power delivery network layer PDN may be formed on the bottom surface of the substrate 100. The power delivery network layer PDN may be formed to apply a positive voltage or a negative (ground) voltage to the first to third power lines M1_R1, M1_R2, and M1_R3.

According to one or more embodiments, a substrate recess may be formed in an upper portion of a substrate, and a penetration hole may be formed to penetrate neighboring elements (e.g., first and second interlayer insulating layers and a device isolation pattern), which are formed of the same or similar insulating material, and to extend into the substrate recess. Since the substrate recess is formed, the penetration hole may be formed by removing the neighboring elements, without a process of etching the substrate. As a result, it may be possible to simplify a process condition for an etching process, which is performed to form the penetration hole. Thus, the productivity of the semiconductor device may be improved.

In one or more embodiments, the neighboring elements may be selectively removed during the etching process for forming the penetration hole. That is, in the etching process, the neighboring elements may be removed, but the substrate may not be removed or may be less removed. Thus, even when the penetration hole is misaligned, it may be possible to prevent or suppress a portion of the substrate, which is adjacent to the substrate recess in a horizontal direction, from being unintentionally removed. As a result, it may be possible to reduce a process failure, which may occur when the penetration hole is misaligned. Thus, the productivity of the semiconductor device may be improved.

In the above embodiments, the penetration via structure TVS and the backside via pattern BV are described as penetrating the substrate 100. However, the disclosure may also apply to a semiconductor device in which the substrate 100 is replaced with a backside isolation layer formed of an insulating material such as silicon oxide (e.g., SiO₂), not being limited thereto, according to one or more other embodiments. In these embodiments, as the substrate 100 is replaced with the backside isolation layer at a backside process, an interfacial surface (boundary or connection surface) may be formed between the backside isolation layer and the second region R2 of the device isolation pattern ST, where the inner side surface of the substrate recess SRS and the second top surface 1b of the substrate 100 are formed before the substrate 100 is replaced by the backside isolation layer.

In the above embodiments, the transistor structures formed by the channel structures CH1 and CH2, the gate electrodes GE and the source/drain patterns SD1 and SD2 are described as a nanosheet transistor including the semiconductor patterns vertically spaced apart from each other. However, the disclosure may also apply to a semiconductor device formed of other types of transistor structure such as fin-field effect transistor (FinFET) and forksheet transistor, not being limited thereto, according to one or more other embodiments.

Although selected embodiments have been particularly shown and described, it will be understood by one of ordinary skill in the art that variations to these embodiments in form and detail may be made without departing from the spirit and scope of the disclosure including the attached claims.

What is claimed is:

1. A semiconductor device, comprising:
an active pattern on a substrate;
a substrate recess formed in an upper portion of the substrate in a third direction intersecting a bottom surface of the substrate;
a first interconnection layer above the active pattern in the third direction;
a power delivery network layer below the bottom surface of the substrate in the third direction; and
a penetration via structure electrically connecting the first interconnection layer to the power delivery network layer,
wherein the penetration via structure is provided in the substrate recess, and
wherein a side surface of the penetration via structure is spaced apart from an inner side surface of the substrate recess.

2. The semiconductor device of claim 1, further comprising:
a p-type metal-oxide-semiconductor field-effect transistor (PMOSFET) region and an n-type metal-oxide-semiconductor field-effect transistor (NMOSFET) region, which are provided on the substrate to be adjacent to each other in a first direction, and
a tap cell region provided adjacent to each of the PMOSFET region and the NMOSFET region in a second direction,
wherein the substrate recess is provided in the tap cell region, and
wherein the first and second directions are parallel to the bottom surface of the substrate and are non-parallel to each other.

3. The semiconductor device of claim 1, wherein the active pattern comprises a first active pattern and a second active pattern, which are adjacent to each other in a first direction parallel to the bottom surface of the substrate,
wherein the first and second active patterns are extended in a second direction crossing the first direction, and
wherein a width of the first active pattern is larger than a width of the substrate recess, in the second direction.

4. The semiconductor device of claim 1, wherein a width of the substrate recess is larger than a width of the penetration via pattern in a first direction parallel to the bottom surface of the substrate.

5. The semiconductor device of claim 1, wherein the penetration via structure comprises a penetration via pattern and a penetration barrier pattern enclosing a side surface of the penetration via pattern, and
a width of the penetration via pattern in a direction parallel to the bottom surface of the substrate increases as a height in a direction perpendicular to the bottom surface of the substrate increases.

6. The semiconductor device of claim 1, further comprising a device isolation trench defining the active pattern,
wherein the substrate comprises a first top surface on an inner bottom surface of the device isolation trench and a second top surface on an inner bottom surface of the substrate recess, and
wherein the second top surface is located at a level lower than the first top surface.

7. The semiconductor device of claim 6, wherein a bottom surface of the penetration via structure is substantially coplanar with the second top surface of the substrate.

8. The semiconductor device of claim 1, further comprising a device isolation pattern comprising a first region, which is provided to enclose the active pattern, and a second region, which is placed below the first region to fill the substrate recess,
wherein the penetration via pattern penetrates the first and second regions of the device isolation pattern.

9. The semiconductor device of claim 8, wherein a bottom surface of the penetration via pattern is substantially coplanar with a bottom surface of the second region of the device isolation pattern.

10. The semiconductor device of claim 8, wherein the second region of the device isolation pattern is interposed between the substrate and the penetration via pattern.

11. A semiconductor device, comprising:
an active pattern on a substrate;
a device isolation pattern comprising a first region enclosing the active pattern and a second region filling a recess formed in an upper portion of the substrate;
a first interconnection layer above the active pattern in a third direction intersecting a bottom surface of the substrate;
a power delivery network layer below a bottom surface of the substrate in the third direction; and
a penetration via pattern electrically connecting the first interconnection layer to the power delivery network layer,
wherein the penetration via pattern penetrates the first and second regions of the device isolation pattern.

12. The semiconductor device of claim 11, wherein a width of the second region of the device isolation pattern is larger than a width of the penetration via pattern in a first direction parallel to the bottom surface of the substrate.

13. The semiconductor device of claim 11, wherein the second region of the device isolation pattern is interposed between the substrate and the penetration via pattern.

14. The semiconductor device of claim 11, wherein a bottom surface of the penetration via pattern is substantially coplanar with a bottom surface of the second region of the device isolation pattern.

15. The semiconductor device of claim 11, wherein the substrate has a first top surface, which is in contact with a bottom surface of the first region of the device isolation pattern, and a second top surface, which is in contact with a bottom surface of the second region of the device isolation pattern.

16. The semiconductor device of claim 15, wherein a bottom surface of the penetration via pattern is substantially coplanar with the second top surface of the substrate.

17. The semiconductor device of claim 11, further comprising an interlayer insulating layer between the device isolation pattern and the first interconnection layer,
wherein the penetration via pattern penetrates the interlayer insulating layer and extends into the device isolation pattern.

18. A semiconductor device, comprising:
an active pattern on a substrate;
a device isolation pattern comprising a first region enclosing the active pattern and a second region filling a recess formed in an upper portion of the substrate;
a channel structure on the active pattern;
a source/drain pattern connected to the channel structure;
a gate electrode on the channel structure;
an active contact connected to the source/drain pattern;
a first interconnection layer above the active contact in a third direction intersecting a bottom surface of the substrate;
a power delivery network layer below a bottom surface of the substrate; and
a penetration via pattern electrically connecting the first interconnection layer to the power delivery network layer,
wherein the penetration via pattern penetrates the first and second regions of the device isolation pattern.

19. The semiconductor device of claim 18, wherein a bottom surface of the penetration via pattern is substantially coplanar with a bottom surface of the second region of the device isolation pattern.

20. The semiconductor device of claim 18, wherein the second region of the device isolation pattern is interposed between the penetration via pattern and the substrate.
